(19) United States
(12) Patent Application Publication
(10) Pub. No.: US 2025/0139339 A1
(43) Pub. Date: May 1, 2025

(54) GRAPHICAL USER INTERFACE FOR QUANTUM CIRCUIT DESIGN

(71) Applicant: Classiq Technologies LTD., Tel Aviv (IL)

(72) Inventors: Amir Naveh, Haifa (IL); Shmuel Ur, Shorashim (IL); Avi Elazari, Hod-Hasharon (IL); Nadav Yoran, Tel-Aviv (IL); Adam Goldfeld, Tel-Aviv (IL); Yehuda Naveh, Tel-Aviv Yafo (IL)

(21) Appl. No.: 18/385,657

(22) Filed: Oct. 31, 2023

(51) Int. Cl. G06F 30/31; G06N 10/20

(52) U.S. Cl. CPC G06F 30/31; G06N 10/20

(57) ABSTRACT

A Graphical User Interface (GUI) is used to display a graphical representation of an abstract quantum circuit. The abstract quantum circuit includes input ports, output ports, wires, and instances. At least one of the instances is an abstract instance of a module that represents a duplication of a quantum operation defined by the module. The abstract quantum circuit is compiled to obtained a quantum circuit. Compiling the abstract quantum circuit comprises replacing the abstract instance with a plurality of instances of the module, whereby concretizing the abstract instance.

### TECHNICAL FIELD

The present disclosure relates to quantum computing in general, and to providing Graphical User Interface (GUI) to be used for designing a quantum circuit, in particular.

### BACKGROUND

Quantum computing is a computational paradigm that is fundamentally different from classic computing. In contrast to classic computing, which utilizes bits, quantum computing utilizes qubits. The qubits have unique features, as each qubit can be in superposition, several qubits can be entangled, and all operations on qubits, referred to as quantum gates, must be reversible (e.g., besides measurements). Temporarily computed values are stored on additional helper qubits, referred to as auxiliary qubits.

### BRIEF SUMMARY

One exemplary embodiment of the disclosed subject matter is a method comprising: displaying, via a Graphical User Interface (GUI), a first portion of an abstract quantum circuit, wherein the GUI enables a user to view a graphical representation of the abstract quantum circuit, the abstract quantum circuit represents a quantum circuit, the abstract quantum circuit comprises: one or more input ports, each of which representing an input register; one or more output ports, each of which representing an output register; one or more instances of modules, each of which having a set of one or more input pins and a set of one or more output pins, wherein each of the modules represents an operation to be performed on values inputted on the set of one or more input pins causing output to be provided on the set of one or more output pins; and wires, each of which connecting between a value feeding element and a value receiving element, the value feeding element is one of an output pin and an input port, the value receiving element is one of an output port and an input pin; wherein at least one of the instances is an abstract instance of a module, the module representing a quantum operation, the abstract instance representing a duplication of the quantum operation within the quantum circuit; in response to a user instruction to the GUI, changing presented display to the user, whereby showing to the user a second portion of the abstract quantum circuit; and compiling the abstract quantum circuit to obtain the quantum circuit, wherein said compiling comprises replacing the abstract instance with a plurality of instances of the module, whereby concretizing the abstract instance.

Another exemplary embodiment of the disclosed subject matter is an apparatus comprising: a screen display, a processor, and a memory, wherein said processor being adapted to perform: displaying on said screen display a Graphical User Interface (GUI), wherein the GUI displays a first portion of an abstract quantum circuit, wherein the GUI enables a user to view a graphical representation of the abstract quantum circuit, the abstract quantum circuit represents a quantum circuit, the abstract quantum circuit comprises: one or more input ports, each of which representing an input register; one or more output ports, each of which representing an output register; one or more instances of modules, each of which having a set of one or more input pins and a set of one or more output pins, wherein each of the modules represents an operation to be performed on values inputted on the set of one or more input pins causing output to be provided on the set of one or more output pins; and wires, each of which connecting between a value feeding element and a value receiving element, the value feeding element is one of an output pin and an input port, the value receiving element is one of an output port and an input pin; wherein at least one of the instances is an abstract instance of a module, the module representing a quantum operation, the abstract instance representing a duplication of the quantum operation within the quantum circuit; in response to a user instruction to the GUI, changing presented display to the user, whereby showing to the user a second portion of the abstract quantum circuit using said screen display; and compiling the abstract quantum circuit to obtain the quantum circuit, wherein said compiling comprises replacing the abstract instance with a plurality of instances of the module, whereby concretizing the abstract instance.

Yet another exemplary embodiment of the disclosed subject matter is a computer program product comprising a non-transitory computer readable medium retaining program instructions, which program instructions when read by a processor, cause the processor to perform a method comprising: displaying, via a Graphical User Interface (GUI), a first portion of an abstract quantum circuit, wherein the GUI enables a user to view a graphical representation of the abstract quantum circuit, the abstract quantum circuit represents a quantum circuit, the abstract quantum circuit comprises: one or more input ports, each of which representing an input register; one or more output ports, each of which representing an output register; one or more instances of modules, each of which having a set of one or more input pins and a set of one or more output pins, wherein each of the modules represents an operation to be performed on values inputted on the set of one or more input pins causing output to be provided on the set of one or more output pins; and wires, each of which connecting between a value feeding element and a value receiving element, the value feeding element is one of an output pin and an input port, the value receiving element is one of an output port and an input pin; wherein at least one of the instances is an abstract instance of a module, the module representing a quantum operation, the abstract instance representing a duplication of the quantum operation within the quantum circuit; in response to a user instruction to the GUI, changing presented display to the user, whereby showing to the user a second portion of the abstract quantum circuit; and compiling the abstract quantum circuit to obtain the quantum circuit, wherein said compiling comprises replacing the abstract instance with a plurality of instances of the module, whereby concretizing the abstract instance.

In some embodiments, the abstract instance is presented in the GUI with an instance instruction, the instance instruction indicates a number of times the module is to be duplicated and connected sequentially, whereby defining a number of the plurality of instances of the module that replace the abstract instance.

In some embodiments, the module comprising an input pin set and an output pin set, a number of input pins in the input pin set is equal to a number of output pins in the output pin set, wherein the plurality of instances of the module comprises a first instance and a second instance, wherein said replacing the abstract instance with the plurality of instances further comprises: for each output pin in the output pin set of the first instance, adding a wire that connects the each output pin with a different input pin of the input pin set of the second instance, whereby each input pin in the input pin set of the second instance is configured to receive a value that is fed from a different output pin in the output pin set of the first instance, whereby creating a sequence of instances that pass values therebetween.

In some embodiments, a mapping between output pin set of the first instance and between the input pin set is defined based on a definition of the module.

In some embodiments, the mapping is defined based on an order of the input pin set in the module and the output pin set in the module, whereby enabling the user to change the mapping via the GUI by editing the module.

In some embodiments, the mapping is defined based on displayed height order of input and output ports in a definition of the module, whereby enabling the user to change the mapping via the GUI by editing the module.

In some embodiments, the abstract instance is presented in the GUI with a cascade instruction, the cascade instruction indicates an input pin of the module that is configured to receive different subsets of register value fed to the input pin, wherein said replacing the abstract instance with the plurality of instances of the module comprises: dividing a size of the register value fed to the input pin by a size of the register to be received by the input pin, whereby computing a number of the plurality of instances to be used to replace the abstract instance; and for each instance of the plurality of instances, feeding a different subset of the register value to a respective input pin thereof, whereby duplicating the quantum operation within the quantum circuit each time with respect to a different portion of the register value.

In some embodiments, the size of the register to be received by the input pin is N, wherein the size of the register value fed to the input pin is M, wherein the number of the plurality of instances is M/N, wherein instance number i of the plurality of instances is fed with bits of range [N·(i−1) . . . (N·i)−1] from the register value, whereby defining the different portion using different offsets in the register value.

In some embodiments, the abstract instance is presented in the GUI with an app parameter instruction, the app parameter instruction indicates, for each instance of the plurality of instances, whether an internal module of the module is to be replaced by an identity module within the instance.

In some embodiments, the app parameter instruction has a value parameter, the value parameter defines for an i-th instance of the plurality of instances whether to use the internal module or to replace the internal module with the identity module, based on a value of the i-th digit of the value parameter in binary basis.

In some embodiments, the method further comprises: in response to an edit user instruction to the GUI, modifying an abstract command associated with the abstract instance, wherein the abstract command effects a manner in which the abstract instance is replaced in said replacing, thereby changing how the abstract instance is concretized.

In some embodiments, the abstract command is at least one of: a cascade instruction or a parameter thereof; an instance instruction or a parameter thereof; an app parameter instruction or a parameter thereof, wherein the app parameter instruction defines for different instances to replace an internal module in the module with an identity module; and a usage of an index parameter in a definition of the module, wherein the usage of the index parameter defines different functionalities for different instances of the module that replace the abstract instance.

In some embodiments, the GUI is a hierarchical GUI enabling editing and display of the abstract quantum circuit, wherein said displaying the first portion of the abstract quantum circuit displays the abstract quantum circuit at a first hierarchical level, wherein the user instruction is an instruction to edit the abstract instance, whereby causing the GUI to display the abstract quantum circuit at a second hierarchical level, the second hierarchical level is a lower level than the first hierarchical level, wherein an input pin of the module is shown in the second hierarchical level as an input port, wherein an output pin of the module is shown in the second hierarchical level as an output port, wherein the module comprises an internal module that is not displayed in the first portion and is displayed in the second portion.

In some embodiments, in the second hierarchical level, an index parameter is utilized in the definition of at least one element in the module, wherein said replacing the abstract instance with a plurality of instances comprises: providing for each instance of the plurality of instances a different value for the index parameter, whereby enabling i-th and j-th instances to differ based on the definition of the at least one element.

In some embodiments, the method further comprising providing the quantum circuit for execution by a quantum execution platform.

### THE BRIEF DESCRIPTION OF THE SEVERAL VIEWS OF THE DRAWINGS

The present disclosed subject matter will be understood and appreciated more fully from the following detailed description taken in conjunction with the drawings in which corresponding or like numerals or characters indicate corresponding or like components. Unless indicated otherwise, the drawings provide exemplary embodiments or aspects of the disclosure and do not limit the scope of the disclosure. In the drawings:

FIGS. 1A and 1B show an exemplary abstract quantum circuit and a corresponding quantum circuit, in accordance with some exemplary embodiments of the disclosed subject matter;

FIGS. 2A and 2B show an exemplary abstract quantum circuit and a corresponding quantum circuit, in accordance with some exemplary embodiments of the disclosed subject matter;

FIGS. 3A and 3B show an exemplary abstract quantum circuit and a corresponding quantum circuit, in accordance with some exemplary embodiments of the disclosed subject matter;

FIGS. 3C and 3D-3E show an exemplary abstract quantum circuit and two corresponding quantum circuits, in accordance with some exemplary embodiments of the disclosed subject matter;

FIGS. 4A-4D show a GUI displaying different portions of an abstract quantum circuit, in accordance with some exemplary embodiments of the disclosed subject matter;

FIG. 5A shows an exemplary abstract quantum circuit that include an abstract instance of a module, in accordance with some exemplary embodiments of the disclosed subject matter;

FIG. 5B shows a module definition of the module, in accordance with some exemplary embodiments of the disclosed subject matter;

FIG. 5C shows a module definition of the module, in accordance with some exemplary embodiments of the disclosed subject matter;

FIG. 6 shows an exemplary flowchart diagram of a method, in accordance with some exemplary embodiments of the disclosed subject matter; and

FIG. 7 shows an exemplary block diagram of an apparatus, in accordance with some exemplary embodiments of the disclosed subject matter.

### DETAILED DESCRIPTION

One technical problem dealt with by the disclosed subject matter is enabling quantum circuit designers to view, review, update, and compile, a complicated quantum circuit using a Graphical User Interface (GUI). In some exemplary embodiments, it may be desired that the modeling displayed in the GUI may be useable by a compiler as an input for compilation once the designer decides the circuit is ready.

Quantum circuits and various optimizations thereof, including GUIs for defining or viewing them are disclosed in U.S. Pat. No. 11,288,589, “QUANTUM CIRCUIT MODELING”, issued Mar. 29, 2022; U.S. Pat. No. 11,620,564, “CSP-BASED QUANTUM CIRCUIT MODELING”, issued Apr. 4, 2023; U.S. Pat. No. 11,294,797, “A DEBUGGER FOR QUANTUM COMPUTERS”, issued Jun. 22, 2021, U.S. Pat. No. 11,429,512, “CONTROLLED PROPAGATION IN QUANTUM COMPUTING”, issued Aug. 30, 2022; U.S. application Ser. No. 17/354,453, “EFFICIENT EXECUTION OF A QUANTUM PROGRAM”, filed Jun. 22, 2021; U.S. patent application Ser. No. 17/450,584, “A FUNCTIONAL-LEVEL PROCESSING COMPONENT FOR QUANTUM COMPUTERS”, filed Oct. 12, 2021; U.S. Pat. No. 11,373,114, “CSP-BASED SYNTHESIS OF A QUANTUM CIRCUIT”, issued Jun. 28, 2022; U.S. application Ser. No. 17/977,300, “COMPILING QUANTUM PROGRAMS”, filed Oct. 31, 2022; U.S. patent application Ser. No. 17/649,576, “CONTROLLED PROPAGATION OF INPUT VALUES IN QUANTOM COMPUTING”, filed Feb. 1, 2022; U.S. application Ser. No. 17/450,583, “PROVISIONING FUNCTIONAL-LEVEL INFORMATION TO BE UTILIZED IN GATE-LEVEL PROCESSING OF QUANTUM CIRCUITS”, filed Oct. 12, 2021; U.S. Pat. No. 11,281,988, “RE-GENERATION OF A GATE-LEVEL QUANTUM CIRCUIT BASED ON GATE-LEVEL ANALYSIS”, issued Mar. 22, 2022; U.S. application Ser. No. 17/499,082, “DYNAMIC SYNTHESIS OF GATE-LEVEL IMPLEMENTATIONS OF FUNCTIONAL BLOCKS IN QUANTUM CIRCUITS”, filed Oct. 12, 2021; U.S. application Ser. No. 17/648,691, “AUXILIARY QUBITS ANALYSIS BASED ON PARTIAL COMPILATION OF QUANTUM PROGRAMS”, filed Jan. 24, 2022; U.S. application Ser. No. 17/810,661, “GENERATING A GRAPHICAL REPRESENTATION OF A QUANTUM CIRCUIT”, filed Jul. 5, 2022; U.S. Pat. No. 11,615,337, “DETERMINING QUANTUM ERROR CORRECTION SCHEMES”, issued Mar. 28, 2023; U.S. application Ser. No. 17/723,561, “DETERMINING DYNAMIC QUANTUM ERROR CORRECTION SCHEMES”, filed Apr. 19, 2022; U.S. Pat. No. 11,416,762, “SELECTING PHYSICAL QUBITS FOR QUANTUM ERROR CORRECTION SCHEMES”, issued Aug. 16, 2022; U.S. application Ser. No. 17/664,742, “AUXILIARY QUBIT DETECTION IN QUANTUM CIRCUITS”, filed May 24, 2022; U.S. application Ser. No. 17/752,282, “AUXILIARY QUBIT VERIFICATION IN QUANTUM CIRCUITS”, filed May 24, 2022; U.S. patent application Ser. No. 18/110,516, “INPUT-BASED MODIFICATION OF A QUANTUM CIRCUIT”, filed Feb. 16, 2023; U.S. application Ser. No. 17/938,347, “SELECTING A QUANTUM COMPUTER”, filed Oct. 6, 2022; U.S. application Ser. No. 18/064,273, “CLASSICAL PREPROCESSING FOR EFFICIENT STATE PREPARATION IN QUANTUM COMPUTERS”, filed Dec. 11, 2022; U.S. application Ser. No. 17/817,397, “DETECTING A FUNCTION SECTION IN A REPRESENTATION OF A QUANTUM CIRCUIT”, filed Aug. 4, 2022; U.S. application Ser. No. 17/929,703, “PERFORMANCE ANALYSIS OF QUANTUM PROGRAMS”, filed Sep. 4, 2022; U.S. patent application Ser. No. 17/938,346, “SELECTING A QUANTUM COMPUTER”, filed Oct. 6, 2022; U.S. patent application Ser. No. 18/201,381, “AUTOMATIC QUANTUM CIRCUIT CONTROL SKIPS”, filed May 24, 2023; U.S. patent application Ser. No. 18/360,079, “EFFICIENT HAMILTONIAN EXPONENTIATION IN A QUANTUM CIRCUIT”, filed Jul. 27, 2023; U.S. patent application Ser. No. 18/360,047, “DETERMINING AN IMPLEMENTATION OF A QUANTUM PROGRAM THAT HAS A MINIMIZED OVERALL ERROR RATE”, filed Jul. 27, 2023; U.S. patent application Ser. No. 18/360,032, “OPTIMAL QUANTUM FUNCTION IMPLEMENTATIONS BASED ON FUNCTION INPUTS”, filed Jul. 27, 2023; all of which are hereby incorporated by reference in their entirety for all purposes, and without giving rise to disvowment.

Quantum algorithms have largely been an academic endeavor in the past thirty years. Theoreticians have published well-defined and proven algorithms and have described them in a sound scientific language. However, implementing real-life quantum circuits based on the theoretical academic description is not a straight forward endeavor, and requires significant resource investment of defining thousands or even millions of gates, based on a scheme defined in the academic paper.

In some cases, even designing circuits that implement known algorithms, such as Shor's, Grover's, or HHL's, may turn to be a hard task using existing techniques. For example, an implementation of the Beauregard circuit, which is disclosed in Beauregard, “Circuit for Shor's algorithm using 2n+3 qubits”, Quantum Information and Computation, Vol. 3, No. 2 (2003) pp. 175-185 (hereinafter, “Beauregard Implementation”, which is hereby incorporated by reference in its entirety for all purposes without giving rise to disvowment, may require 4n+2 qubits. For n=4, the circuit may include thousands of gates, and in order to meet certain requirements, may end up requiring over 100,000 physical qubits. The growth of number of qubits and gates may be polynomial if not exponential as n increases.

One technical solution is to provide quantum designers with modeling constructs that enable the designers to define in an abstract manner circuit elements that are to be repeated, in whole or in part, in the quantum circuit. A Graphical User Interface (GUI) enables the designer, also referred to as the user, to view graphical representation of an abstract quantum circuit. The abstract quantum circuit may be a non-executable representation of the quantum circuit in which there is at least one abstract instance of a module. The user may view and edit the abstract quantum circuit. Additionally, or alternatively, the user may edit abstract command associated with the abstract instance, thereby modifying the operation of the quantum circuit that is generated based on the abstract quantum circuit.

In some cases, an abstract quantum circuit may be compiled into an executable quantum circuit. In some cases, the abstract quantum circuit may be a circuit, in which circuit timing is defined. Additionally, or alternatively, the abstract quantum circuit may be a Directed Acyclic Graph (DAG) representation of the circuit, in which partial order between some gates may be defined, but some timings may remain undefined and can be implemented in different ways.

The abstract quantum circuit may comprise: input ports, output ports, instances of modules, and wires. Input and output ports may represent input to and output from the circuit at a hierarchical level that is being shown. At the highest hierarchical level, the ports represent the inputs and outputs to the circuit itself. At lower hierarchical levels, the ports represent inputs and outputs to the relevant portion of the circuit, such as the specific module that is being shown. Instances of modules may represent functional blocks to be used by the quantum circuit. As an example, an instance may be a CNOT gate, a Hadamard gate, or the like. As another example, an instance may represent a multi-gate, multi-circuit functionality. For example, an instance may be an indication to use a Quantum Fourier Transform (QFT) circuit. In some cases, the module that the instance implements may be any sub-circuit having a predetermined functionality. In some cases, the user may manually define the sub-circuit. Additionally, or alternatively, the sub-circuit may be provided in a pre-defined library. Each instance may have input and output pins representing input to and output from the sub-circuit. The wires may connect between elements that provide a value, also referred to as value feeding elements, such as input ports and/or output pins, and between elements that receive a value, also referred to as value receiving elements, such as output ports and/or input pins.

The abstract quantum circuit may include at least one abstract instance of a module. The abstract instance may represent a duplication of a quantum operation that is defined by the module, such that the quantum circuit includes a plurality of instances of the module that are defined by the abstract instance. The abstract instance may be associated with an abstract command that the user may define. In some cases, the abstract command may have a parameter value that the user may define. In some exemplary embodiments, the abstract command may include an instance instruction that indicates the number of times the module is to be duplicated and connected sequentially. The parameter, for example, may be the number of times. Additionally, or alternatively, the abstract command may be a cascade instruction. The cascade instruction may identify an input pin that will receive different subsets of register value fed thereto in different copies of the module. Cascade instruction may define the number of copies based on a ratio between the size of the register fed into the input pin and the size of the input pin. For example, if the register has 100 qubits (qubits 0 . . . 99) and the input pin has a size of 20 qubits, then there will be 5 copies, each receiving a different 20-qubit sub-register of the register; the first copy will receive the value of qubits 0 . . . 19: the second copy-qubits 20 . . . 39; third copy-qubits 40 . . . 59; fourth copy: 60 . . . 79; and fifth copy-qubits 80 . . . 99. Additionally, or alternatively, the abstract command may be an app parameter instruction, indicating for specific copies whether to retain an internal module or replace it with an identity module (I). For example, an abstract instance of a module that utilizes a QFT module as an internal module thereof to implement the quantum operation of the module. The abstract instance may be defined with an app parameter command having a value of 11, which is 1011 in binary. Such value may indicate that the abstract instance is to be replaced with 4 instances of the same module, where the first, third and fourth copies would include the QFT module, and the second copy includes an identity module instead of the QFT module. In this example, each copy is determined whether to include the QFT module or have it replaced by the identity module based on a value of a corresponding digit in the parameter value. The i-th copy would include the target internal module if and only if the value of the corresponding bit in the binary value is 1. If the value is 0, the target internal module may be replaced by the identity module (I). In some exemplary embodiments, the app parameter may define which copies are to use the identity module and which are to use the original target internal module in different manners.

In some exemplary embodiments, the user may interact with the GUI presenting the abstract quantum circuit. The user may update the abstract quantum circuit, and review it or portions thereof. In some cases, the GUI may be a hierarchical GUI enabling editing and displaying of different hierarchies within the abstract quantum circuit. For example, the GUI may display the abstract quantum circuit at a first hierarchical level, and in response to a user instruction to edit the abstract instance, the GUI may display the abstract quantum circuit at a second hierarchical level, that is a lower level than the first hierarchical level (e.g., level N−1, instead of level N). Ath the second hierarchical level, the module may be shown. Each input pin of the module may be shown as an input port in the second level hierarchical display. Each output pin of the module may be shown as an output port in the second hierarchical level display. The second hierarchical level display may display an internal module that is used to implement the quantum operation defined by the module and which is not shown in the first hierarchical level display.

In some exemplary embodiments, the user may utilize an index parameter when defining the module. When the abstract instance is concretized by replacing it with a plurality of copies of the module, each copy may receive a different value for the index parameter, enabling different instances to have a different implementation. For example, the index may be utilized in defining a subset of qubits in a register to be processed, such that the i-th copy, processes different qubits than the j-th copy. As another example, the i-th copy may process a different number of qubits, e.g., qubits 0 . . . i−1, such that the first copy processes a single qubit (0), and the last, N-th copy, processes N qubits (0 . . . N−1).

In some exemplary embodiments, the definition of the module may affect how the instance instruction is implemented. For example, a mapping between the output pins of the i-th copy and the input pins of the (i+1)-th copy may be defined based on the order of the input and output pins. The user may update the order of the input or output pins by modifying the order of the input and output ports in the second hierarchical level. In some cases, the mapping may be defined based on the displayed height order of the input and output ports in a definition of the module.

In some exemplary embodiments, the abstract quantum circuit may be compiled. During compilation, the abstract quantum circuit may be concretized by concretizing the abstract instance. The abstract instance may be replaced by a plurality of instances of the module, based on the abstract command(s). The output of such compilation may be a concrete quantum circuit. The quantum circuit may be given in gate-level form, in functional-level form, in a DAG form, in a defined scheduling order of gates over cycles, or the like. The quantum circuit may be executable (with or without further compilation or transpilation operations) by a quantum computer. In some cases, the user may view, via the GUI, the concrete quantum circuit, thereby enabling the user to view the detailed output of her original abstractly defined abstract quantum circuit.

It is noted that the disclosed subject matter is explained with examples of a single abstract instance in the abstract quantum circuit. However, it will be noted that the abstract quantum circuit may include any number of abstract instances, which may be defined with respect to the same or different modules, connected or not connected therebetween, having the same or different abstract commands and parameters, or the like.

One technical effect of the disclosed subject matter is to provide a compact, yet accurate and precise representation of complex quantum circuits. The abstract quantum circuit may enable users to define highly complex quantum circuits, such as defined in academic papers, in a visual manner, while unambiguously capturing all formal requirements of the quantum circuit. In some exemplary embodiments, the modeling constructs, as well as the synthesis engine may be able to formally understand the model and produce a concrete, optimized quantum circuit implementation, hence reaching for the ability to create complex quantum algorithms from thought to execution.

In some exemplary embodiments, the disclosed subject matter may enable users to visually define and model circuits that implement complex quantum algorithms in a formal way, with potentially hundreds of thousands of circuit elements, and even much more. A human user may not be able to visually comprehend the entire quantum circuit, and hence hierarchical display may be utilized. Furthermore, the different hierarchy may be utilized to encapsulate implementation details and allow the user to create duplicates of the same implementation with different variations. In some cases, a human user may be enabled to define a circuit with over 300,000 circuit elements, while never viewing more than a thousand elements at once, and while never explicitly viewing all 300,000 circuit elements at any point of the design process.

In some exemplary embodiments, the abstract quantum circuit may also be a compact representation in memory of the quantum circuit, enabling a reduced memory utilization in the design process.

The disclosed subject matter may provide for one or more technical improvements over any pre-existing technique and any technique that has previously become routine or conventional in the art. Additional technical problems, solutions and effects may be apparent to a person of ordinary skill in the art in view of the present disclosure.

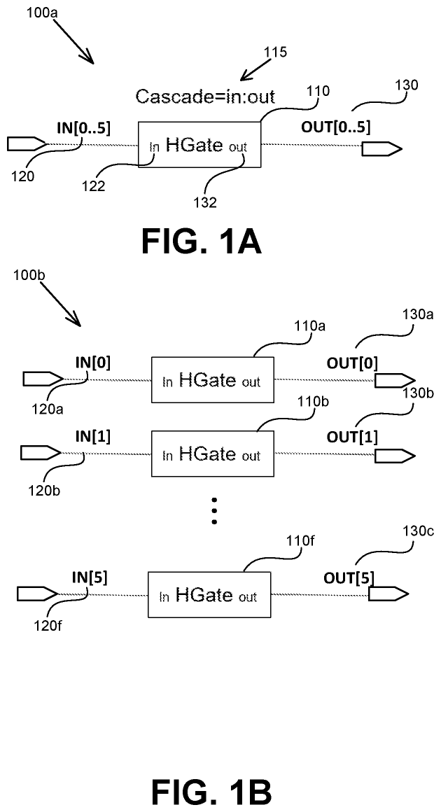

Referring now to FIG. 1A showing an abstract quantum circuit, in accordance with some exemplary embodiments of the disclosed subject matter. Abstract Quantum Circuit 100a is a simplified quantum circuit having an Input Port 120. Input Port 120 providing a 6-qubit register. Input Port 120 is denoted “IN”. Input Port 120 is connected using a wire to an Abstract Instance 110 of an HGate module. Abstract Instance 110 of the HGate Module is shown to have an Input Pin 122, denoted “in”, and an Output Pin 132, denoted “out”. Output Pin 132 is connected using a wire to Output Port 130 of Abstract Quantum Circuit 100a. Output port 130 is a register with six qubits.

Abstract Instance 110 is an abstract instance, as there is an abstract command relating thereto. Specifically, Abstract Instance 110 includes a Cascade Instruction 115. Cascade Instruction 115 indicates a pair of input-output pins of the module (In Pin 122 and Out Pin 132). Cascade Instruction 115 indicates that when the Abstract Instance 110 is replaced with a plurality of instances, the qubits passed to In Pin 122 and provided out from Out Pin 132 are to be cascaded.

It is noted that a GUI displaying Abstract Quantum Circuit 100a may provide a visual indication of Abstract Instance 110 being an abstract instance. For example, abstract instances may have a different color, filling, pattern, or other visual indication that can be used to easily differentiate them from non-abstract instances.

Referring now to FIG. 1B, showing Quantum Circuit 100b that is obtained when Abstract Quantum Circuit 100a is compiled. During compilation, Abstract Instance 110 is replaced by six instances of HGate module (110a, 110b, . . . , 110f). Each instance receives a different qubit from Input Port 120. Quantum Circuit 100b is illustrated with each qubit of Input Port 120, displayed separately (120a, 120b, . . . , 120f). Similarly, Output Port 130 is shown to be split to six 1-qubit ports (130a, 130b, . . . , 130f).

In some exemplary embodiments, the number of instances in Quantum Circuit 100b may be determined based on the relation between the size of input port and the corresponding input pin. For example, HGate module may be defined to receive a single qubit in Input Pin 122. Accordingly, if a 6-qubit register is provided thereto, the qubits of the register are provided to the different instances in a “cascading” pattern. It is noted that HGate module may be configured to be able to receive values in the input pins with a varying width, such as defined by a width parameter, W (not shown). In such a case, the width may be defined by the developer designing the quantum circuit. In this illustrated example, the developer may have defined the width to be one (W=1).

In some exemplary embodiments, cascade instruction may be utilized to provide different subsets of the register value. In the illustrated example, each different subset is of size 1. However, in some cases, the subsets may be a multi-qubit register. For example, the six-qubit register may be split into 3 different 2-qubit sub-registers. In such a case, the cascading instruction may yield three instances of the HGate module. In some exemplary embodiments, during compilation, the abstract instance may be replaced by a plurality of instances. The size of the register value fed to the input pin (e.g., size of Input Port 120, i.e., size 6) may be divided by the size of the register to be received by the input pint (e.g., In Pin 122, i.e., size 1). The outcome may be the number of instances to be used to replace the abstract instance 110 in view of Cascade Instruction 115. Each instance, a different subset of the register value is fed into a respective input pin, as is illustrated in FIG. 1B.

In some exemplary embodiments, the size of the register to be received by the input pin is N. The size of the register value fed to the input pin is M. The number of the plurality of instances (110a, 110b, . . . , 110f) that replace Abstract Instance 110 may be computed to be M N. Each instance may receive a different subset of the register fed to the input pin. Instance number i of the plurality of instances may be fed with bits of range [N·(i−1) . . . (N·i)−1] from the register value. This may define different portions of the register using different offsets in the register value.

In some exemplary embodiments, the duplication pattern exemplified in FIG. 1B may be referred to as a vertical duplication pattern. In a vertical duplication pattern, each instance receives different inputs and outputs, which are independent of the inputs and outputs of the other instances. When the quantum circuit is executed, the different instances in a vertical duplication pattern may be executed in parallel.

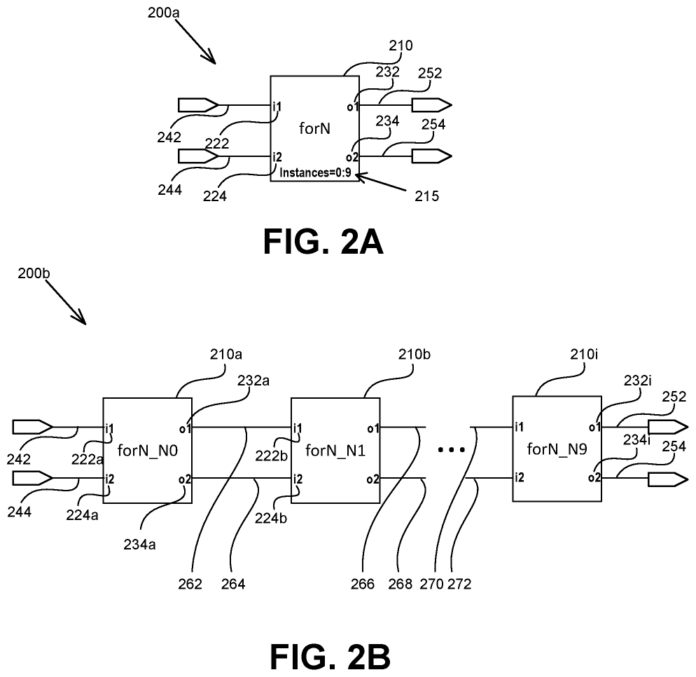

Referring now to FIG. 2A showing an abstract quantum circuit, in accordance with some exemplary embodiments of the disclosed subject matter. Abstract Quantum Circuit 200a is a simplified quantum circuit that includes an Abstract Instance 210 implementing forN module. forN module has two input pins, i1, i2 (222, 224), and two output pins, o1, o2 (232, 234). It is noted that Input Pins 222, 224 and the Output Pins 232, 234 may receive multi-qubit register values and are not limited to a single qubit value. Abstract Quantum Circuit 200a has a first input port that is connected using a Wire 242 to Input Pin i1, 222, and a second input port that is connected using a Wire 244 to Input Pin i2, 224. Similarly, Output Pins o1, 232, and o2, 234, are connected to respective output ports using Wires 252, 254.

Abstract Instance 210 defines an abstract command. The abstract command is an Instance Instruction 215. Instance Instruction 215 may indicate a number of times the module is to be duplicated and connected sequentially. As the plurality of instances that replace the abstract instance is connected sequentially, additional wires may be added to the circuit during compilation.

Referring now to FIG. 2B showing a Quantum Circuit 200b corresponding to the definition of Abstract Quantum Circuit 200a. As Instance Instruction indicated a range 0:9 (i.e., a range of ten item, starting from zero and ending at nine), ten instances of ForN module (210a, 210b, . . . 210i) replace Abstract Instance 210. The instances are connected sequentially. The outputs of Output Pins 232a, 234a of Instance 210a are fed into Input Pins 222b, 224b of Instance 210b, respectively. The outputs are fed thereto using two new Wires 262, 264. Similarly. Wires 266, 268, 270, 272 are utilized to pass quantum state values between the plurality of instances.

In some exemplary embodiments, wires that pass value to the first-ordered instance in the sequence may remain as defined in Abstract Quantum Circuit 200a. For example, Wires 242, 244 may pass values to Input Pins 222a, 224a in Quantum Circuit 200b. Similarly, wires that receive value from the last-ordered instance in the sequence may remain as defined in the Abstract Quantum Circuit 200a. For example, Wires 252, 254 may feed the output values of Output Pins 232i, 234i to the output ports, as defined in Abstract Quantum Circuit 200a.

In some exemplary embodiments, the determination of which output pin is to be connected to which input pin of a next instance may be made based on a mapping. The mapping may map output pins to input pins based on a definition of the module. In some cases, the mapping may be defined based on an order of the input pins in the module and the output pins in the module. The user may update the order using the GUI and as a consequence may change the mapping and how the instances are connected. In some cases, the mapping may be defined based on displayed height order of input and output ports in a definition of the module when shown in the GUI. The GUI may be utilized to edit the definition of the module, at a lower hierarchical level. The pins of the instance may correspond to ports shown at the lower hierarchical level. Changing the height-based order of the ports may affect and change the mapping. As an example, the mapping may be to map the i-th high input port with the i-th high output port.

In some exemplary embodiments, the duplication pattern exemplified in FIG. 2B may be referred to as a horizontal duplication pattern. In a horizontal duplication pattern, the same qubits are passed between the instances in a sequential manner. Each instance is ordered after the previous instance. When the quantum circuit is executed, an order of execution in between the different instances in the horizontal duplication pattern is defined and imposed.

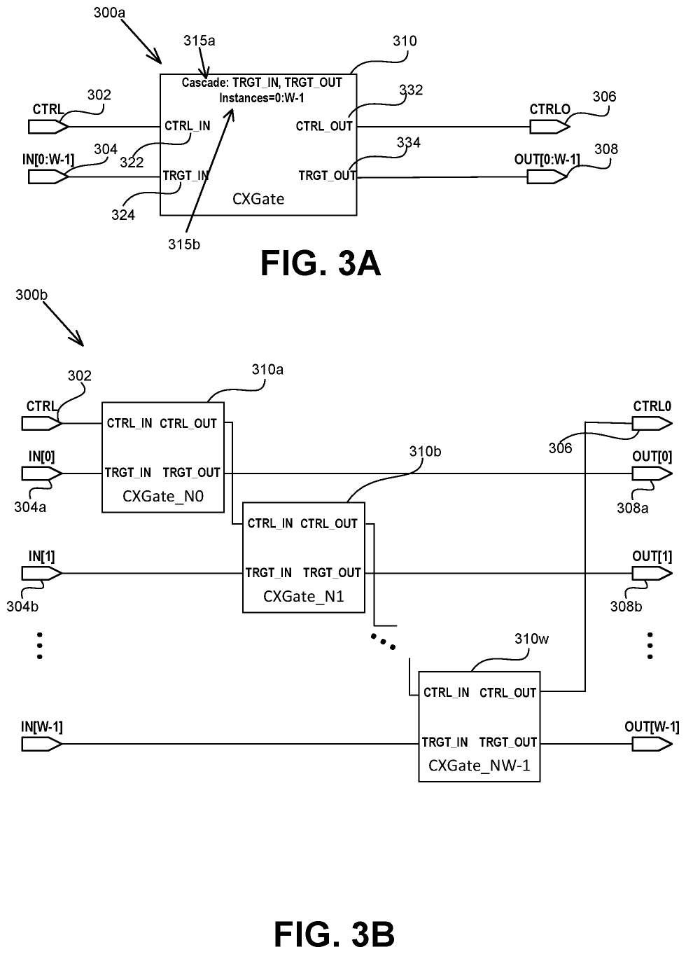

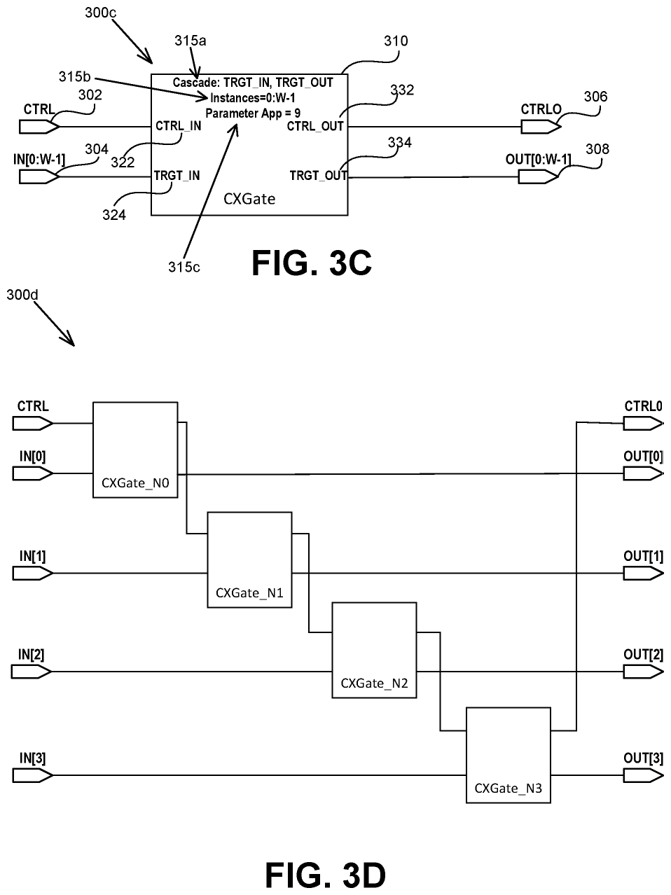

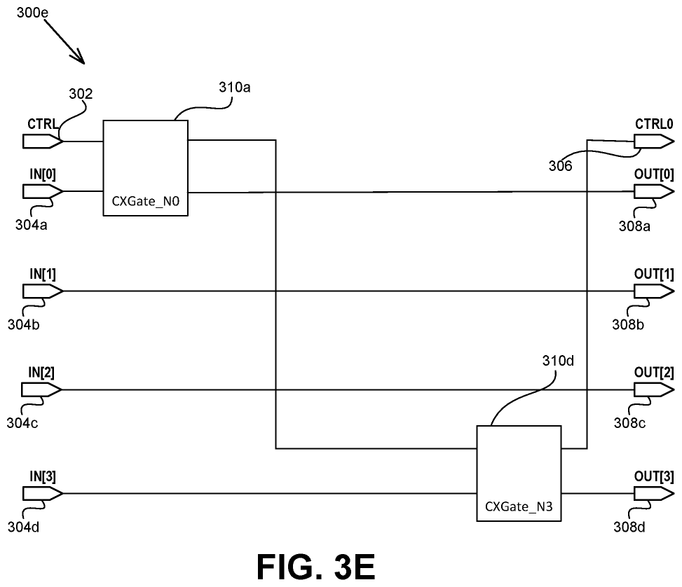

FIG. 3A shows an abstract quantum circuit, in accordance with some exemplary embodiments of the disclosed subject matter. Abstract Quantum Circuit 300a defined an Abstract Instance 310 of CXGate module. Abstract Instance 310 is defined by two abstract commands: Cascade Instruction 315a and Instance Instruction 315b. In this example, Cascade Instruction 315a relates to TRGT_IN and TRGT_OUT pins (324, 334). TRGT_IN Pin 324 is fed with a register of width W, that is provided from Input Port 304. TRGT_OUT Pin 334 feeds a register of width W in Output Port 308.

CXGate is defined to also have a single qubit input pin, CTRL_IN Pin 322 that is fed with a value from Input Port 302. CTRL_OUT Pin 332 feeds CTRLO Output Port 306.

Referring now to FIG. 3B showing a Quantum Circuit 300b corresponding to the definition of Abstract Quantum Circuit 300a. Quantum Circuit 300b includes W instances of CXGate (310a, 310b, . . . , 310w). The value of CTRL_IN pin of each instance is sequentially connected, passing the value of CTRL Input Port 302 until the output value is finally provided to CTRLO Output Port 306. Such sequential connection is an outcome of the Instance Instruction 315b. On the other hand, in view of Cascade Instruction 315a, each instance receives at TRGT_IN input pin a different portion of the register at Input Port 304. Instance 310a receives a IN[0] (304a) and outputs the value directly to OUT [0] (308a), Instance 310b receives a IN[1] (304b) and outputs the value directly to OUT [1] (308b), and so forth.

Referring now to FIG. 3C showing an Abstract Quantum Circuit 300c, in accordance with some exemplary embodiments of the disclosed subject matter. Abstract Instance 310 further includes an App Parameter Instruction 315c. App Parameter Instruction 315 is provided with the value 9, which translates to 1001 in binary. Such value may impute a width W of 4. Additionally, or alternatively, the width may be defined explicitly to be 4 (e.g., using an instruction W=4).

FIG. 3D exemplifies a Quantum Circuit 300d with 4 instances (0 . . . 3) of CXGate when the control signal is connected sequentially, and the input signals are cascaded. As can be appreciated Quantum Circuit 300d is merely an example of Quantum Circuit 300b, when W=4. However, such implementation disregards App Parameter Instruction 315c. In view of the parameter value being 1001 in binary, when Abstract Quantum Circuit 300c is compiled, Abstract Instance 310 is replaced by a plurality of instances of CXGate. The i-th copy is determined to be included in the compiled quantum circuit based on the value of the i-th digit of the parameter value. For example, if the i-th digit is 0, instead of CXGate, the instance would include an identity module (I). If, on the other hand, the i-th digit is 1, CXGate module would be implemented for the i-th copy. FIG. 3E shows a Quantum Circuit 300e that implements CXGate only for the first and fourth copies. The second and third copies implement an Identity module (I) which can be omitted as it does not affect the computation of the circuit. Hence, using App Parameter Instruction 315c together with Cascade Instruction 315a, certain qubits of Input Port 304 remain unchanged while others are processed by a CXGate module. In this example, the first and fourth qubits (304a, 304d) are processed and outputted to Output Port (308a, 308d), while the second and third qubits (304b, 304c) remain unprocessed and unchanged and fed AS IS into respective output ports 308b, 308c.

In some exemplary embodiments, an app parameter instruction may be utilized the developer to load a desired quantum number into the quantum circuit. Instead of manually defining a circuit, such as Quantum Circuit 300e, the same effect can be achieved easily using an app instruction as shown in Abstract Quantum Circuit 300c. It is noted that such a design is easier to maintain and update, as changing the value is simple and straightforward and can be achieved without the user having to change wire connectivity of the relevant sub-circuit. Instead, the developer may simply change the value of the parameter for the app parameter instruction. Furthermore, it may be easier for a human developer to understand the functionality of the sub-circuit that is represented by a single abstract instance such as 310 of FIG. 3C, as opposed to reviewing the sub-circuit equivalent thereto that is shown in FIG. 3E.

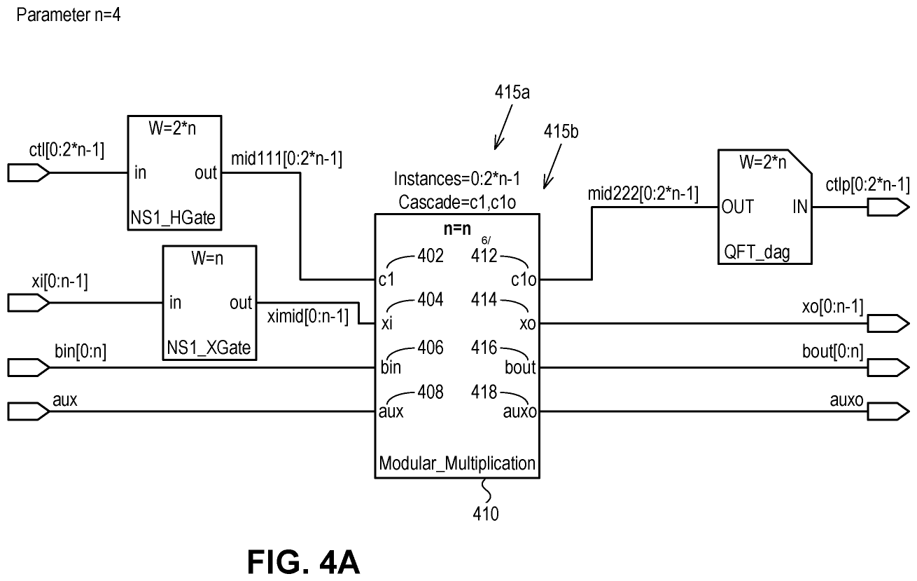

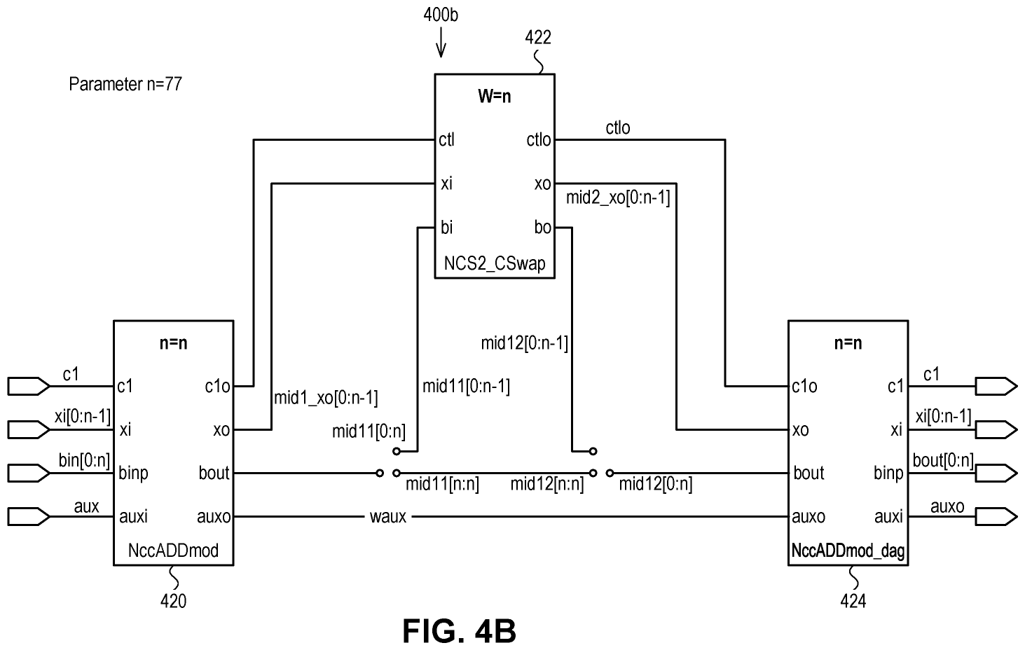

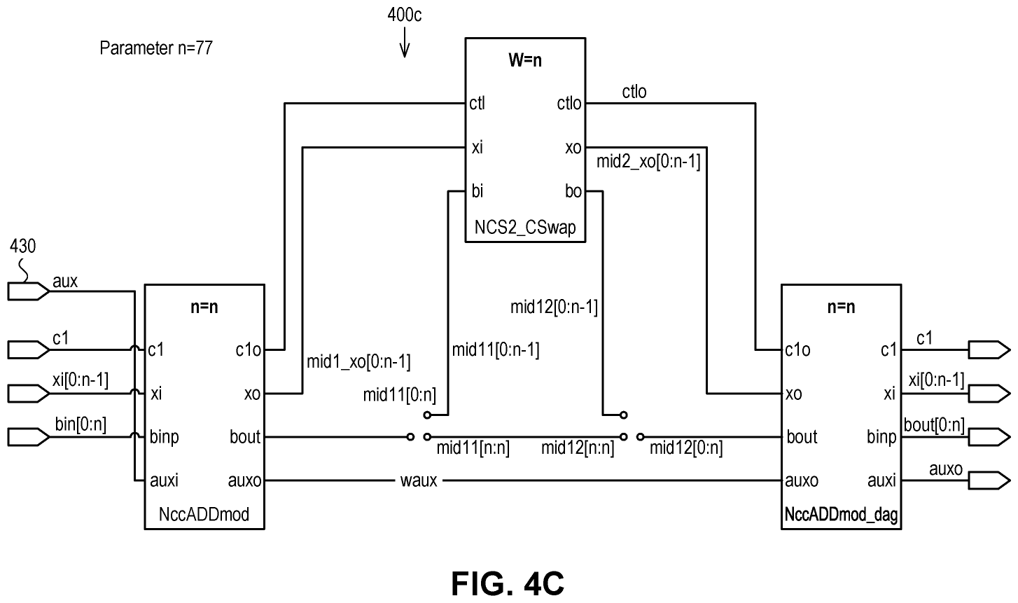

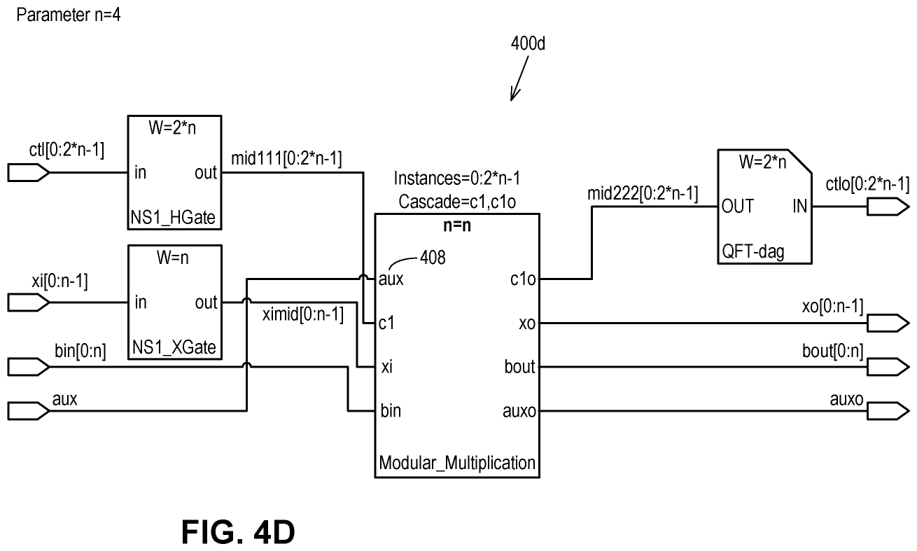

Referring now to FIGS. 4A-4D, which show a GUI displaying different portions of an abstract quantum circuit, in accordance with some exemplary embodiments of the disclosed subject matter. FIG. 4A shows a high-level abstract quantum circuit implementing Shor's algorithm according to Beauregard Implementation. Abstract Quantum Circuit 400a includes Abstract Instance 410 of Modular Multiplication module. Modular Multiplication module has four input pins, cl (402), xi (404), bin (406) and aux (408). Modular Multiplication module has four output pins, clo (412), xo (414), bout (416) and auxo (418). Abstract Instance 410 includes both an Instance Instruction 415a and Cascade Instruction 415b, with respect to cl input pin (402), clo output pin (412).

The user may view the definition of the Modular Multiplication module, such as by clicking on Abstract Instance 410, pointing to, issuing an instruction, or using other user interactions. FIG. 4B shows an example of a Quantum Circuit 400b serving as the definition of the Modular Multiplication module. Quantum Circuit 400b shows a hierarchical level that is lower by one level than the level of Abstract Quantum Circuit 400a. In some exemplary embodiments, Quantum Circuit 400b may be an abstract quantum circuit as it may include one or more abstract instances. In some exemplary embodiments, Quantum Circuit 400b may include one or more internal modules, such as for example NccADDmod 420, NCS2 CSwap 422, NccADDmod^{†} 424, which are not visible to the user when viewing the higher hierarchy (400a).

As explained above, connectivity between consecutive copies that implement the Modular Multiplication module may be defined based on an order of the pins of such module. When considering the set of pins that are to be sequentially connected (input pins: xi, bin, aux; and output pins: xo, bout, auxo), the wires may be connected based on a respective order of the pins. For example, height-based order is a simple visually comprehensible ordering that can be used. Based on such order, the output of xo (414) is fed into x/input pin 404 of the successive instance of the Modular Multiplication module. Similarly, output of bout 416 is fed as input to bin 406 and output of auxo 418 is fed as input to aux 408.

In some exemplary embodiments, if the user wishes to change the mapping, the user may do so by editing Quantum Circuit 400b. FIG. 4C shows Quantum Circuit 400c after the user had edited Quantum Circuit 400b. In some exemplary embodiments, aux Input Port 430 may have been moved so as to be positioned at a highest position with respect to the other input ports. Accordingly, at a higher hierarchy level, Abstract Quantum Circuit 400d may be viewed. Abstract Instance 410 has been affected by the change in a manner that is visible to the user. Aux input pin (408), which corresponds to aux Input Port 430 now appears as the first-ordered input pin. Accordingly, the mapping may now be xo (414) fed into aux (408), bout (416) is fed into xi (404), auxo (418) is fed into bin (416). It is noted that in some cases, the pins may have a different width of registers. A compilation error may be issued when there is a mismatch of widths in the mappings. In some cases, a visual indication may be shown on the screen as such mismatch may be identifiable based on static analysis and prior to compilation. Additionally, or alternatively, the mapping may map qubits to qubits irrespective of registers. For example, consider the current example, in which xi/xo have n qubits, bin/bout have n+1 qubits, and aux/auxo have one qubit. Under the new definition, the following mapping may be implemented:
xo[0]→aux
xo[1: n−1]→xi [0:n−2]
bout[0]→xi[n−1]
bout[1:n]→bin[0:n−1]
auxo→bin[n]

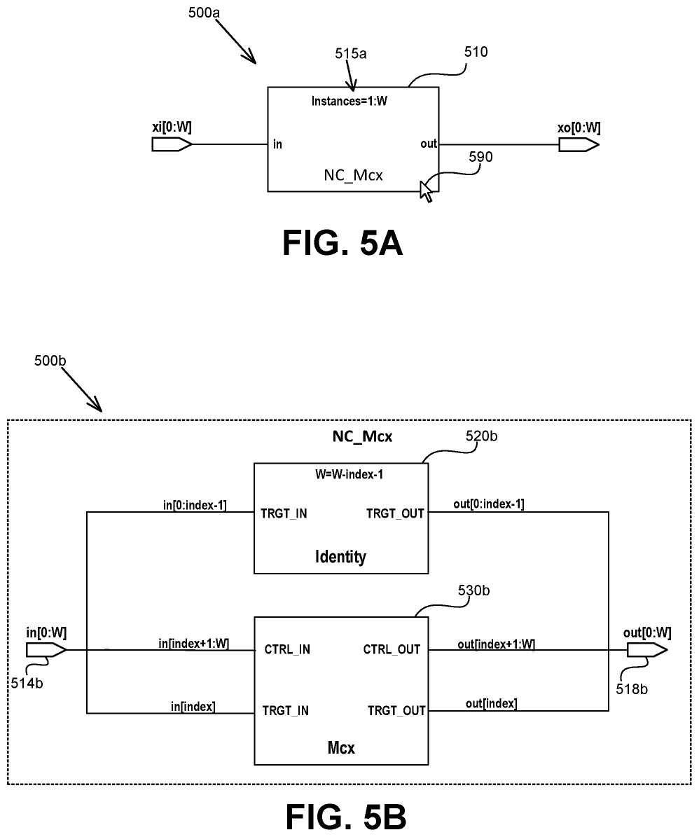

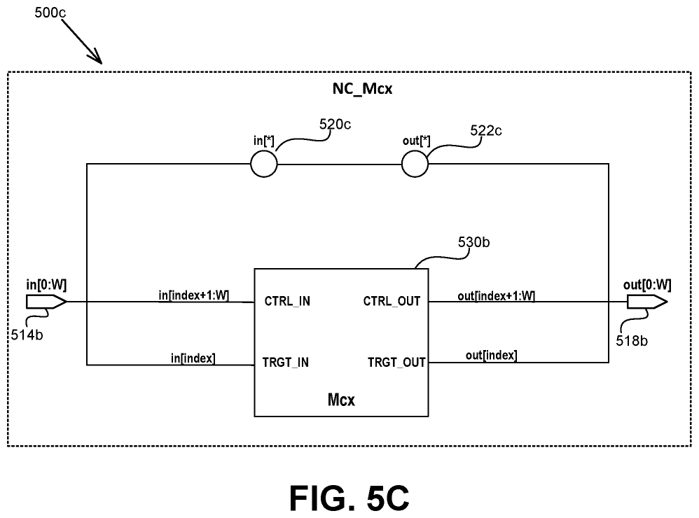

Referring now to FIG. 5A showing an exemplary abstract quantum circuit that include an abstract instance of a module, in accordance with some exemplary embodiments of the disclosed subject matter.

Abstract Quantum Circuit 500a includes Abstract Instance 510 of NC_Mcx module having an Instance Instruction 515a. The user may interact with Abstract Instance 510 using the GUI, such as by pointing to Abstract Instance 510 using a cursor 590 or another pointing instrument.

FIG. 5B shows a module definition of the NC_Mcx module, in accordance with some exemplary embodiments of the disclosed subject matter. The definition may be shown in a GUI display, which displays that circuit elements and further displays the name of the module. In some exemplary embodiments, Quantum Circuit 500b is the definition of the NC_Mcx module which Abstract Instance 510 utilizes. NC_Mcx module is defined using an index parameter. As can be appreciated, Input Port 514b is a register of size W+1. The W+1 qubits are then split into three possible pins: some qubits are passed into an Identity Module 520b; a single qubit is passed to TRGT_IN pin of Instance 530b implementing Mex module; and the remaining qubits are provided to CTRL_IN pin of Instance 530b. The developer is enabled to provide a flexible definition of NC_Mcx module using the index parameter, such that each different instance replacing Abstract Instance 510 receives a different index parameter value, which is then used to provide a different definition. In this example, index qubits are disregarded (e.g., passed to Identity module 520b), a specific qubit serves as the target of the Mex module (Instance 530b; qubit in the index-th position), and the remaining W-index qubits are provided to CTRL_IN pin of Instance 530b. As can be appreciated, this enables the definition to be flexible and allow different qubit to be processed at each copy that is created when replacing the Abstract Instance 510a. In some cases, the index parameter will receive the values defined in the Instance Instruction 515a. In the present example, the first instance that is created is created with the index parameter value 1. The second instance—with the value 2, the third—with value 3, and so forth until reaching the W-th instance, in which the value is W.

Referring now to FIG. 5C which shows a module definition of the NC_Mcx module, in accordance with some exemplary embodiments of the disclosed subject matter. Quantum Circuit 500c is an alternative the definition of the NC_Mcx module that Abstract Instance 510 may utilize. Quantum Circuit 500c is logically equivalent to the definition of Quantum Circuit 500b. The definition of Quantum Circuit 500c utilizes a remainder symbol (e.g., asterisk, “*”) to define a remainder register that is passed via an identity module (not shown). Node 520c represents the remainder qubits of Input Port 514b that were not explicitly utilized in other portions of Quantum Circuit 500c. Similarly, Node 522c represents the remainder qubits of Output Port 518b that were not explicitly utilized in other portions of Quantum Circuit 500c. The remainder symbol enables the developer to define registers that might be complicated for him to explicitly define, e.g., using complicated mathematical formulas, and to avoid human error. If the developer miscomputes the correct indexes, there may be ambiguity (e.g., there may be a contradiction indicating that the same qubit should be utilized in two different places) or an omission (e.g., a specific qubit may not be processed at all). Such omissions or ambiguities may render the quantum circuit as invalid and uncompliable. In some exemplary embodiments, the developer may utilize the remainder symbol to define that all qubits of the relevant register that were not included in other portions of the circuit, should be aggregated into the remainder register. During compilation, the compiler may determine which qubits of the relevant register were not referenced and may aggregate them in the remainder register defined with the remainder symbol. It is noted that the remainder register may include any of the qubits of the original register, including non-consecutive series of qubits (e.g., in[1, 5, 8 . . . 10, 12, 20 . . . 30]).

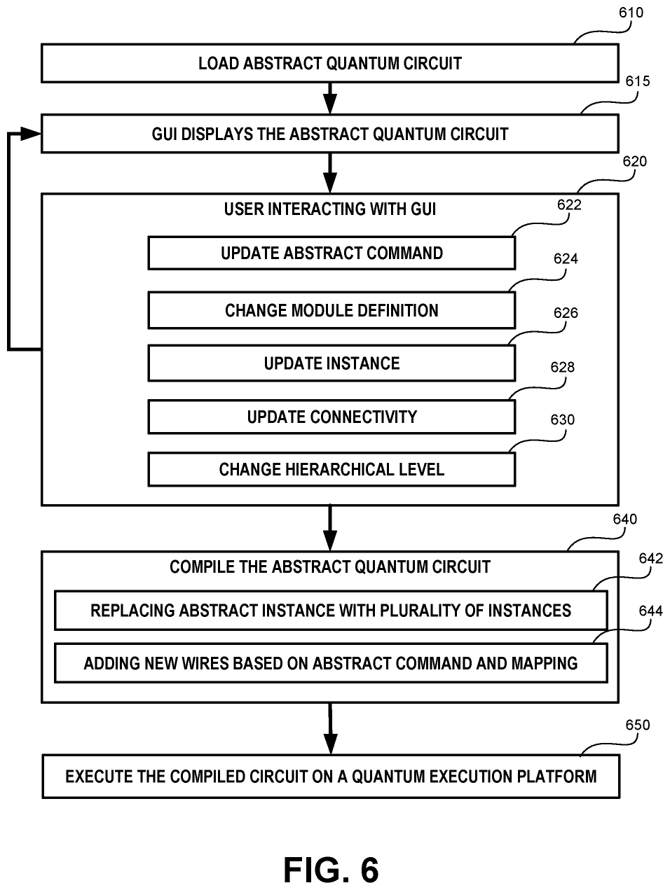

Referring now to FIG. 6 showing an exemplary flowchart diagram of a method, in accordance with some exemplary embodiments of the disclosed subject matter.

In Step 610, an abstract quantum circuit is loaded. The abstract quantum circuit may be loaded from a data storage, such as local storage (e.g., hard disk, disk on key, or the like), remote storage (e.g., Network Attached Storage (NAS), cloud server, storage server, or the like). In some exemplary embodiments, the abstract quantum circuit may be retained in computer-readable format, and may be loaded into memory of a classic computer that is used by a developer designing the abstract quantum circuit. In some cases, the abstract quantum circuit may be loaded for the purpose of compiling the circuit and preparing it for execution.

On Step 615, a GUI may display the quantum circuit computer. The GUI may be a user interface that is used by a developer designing, viewing, reviewing, editing, compiling, or otherwise handling the abstract quantum circuit. In some cases, the GUI may present different portions of the abstract quantum circuit at different times. For example, the GUI may present the abstract quantum circuit at different hierarchical levels. As an example, the circuit may be displayed at a highest hierarchical level, and in response to user interactions therewith, drill-down operations into lower hierarchical levels may be performed and other portions of the abstract quantum circuit may be displayed. Additionally, or alternatively, if the abstract quantum circuit is too big to be shown on a screen display, the user may zoom-in/zoom-out, scroll left/right/up/down, or otherwise change the portion of the abstract quantum circuit that is being displayed (without changing hierarchy level). In some cases, the GUI may display the abstract quantum circuit in a DAG format. Additionally, or alternatively, other manners of display may be utilized, including displays of scheduled gates and cycles. In some cases, drill-down may be performed with respect to instances shown at the present hierarchical level, allowing the user to view the details of the module that is being instanced.

In Step 620, the user may interact with the GUI. In some exemplary embodiments, the user may update an abstract command associated with an abstract instance (622). Additionally, or alternatively, the user may change module definition (624). Additionally, or alternatively, the user may update an instance (626), such as by adding a new instance, deleting an existing instance, changing a width property of an instance, changing the module implemented by the instance, or the like. Additionally, or alternatively, the user may update connectivity in the circuit (628), such as by adding a new wire to connect two elements that were not previously connected, updating an existing wire to connect different elements (e.g. different instances, pins, ports, or the like), deleting an existing wire, or the like. In some cases, the user may change names of registers, ports, pins, instances, wires, or the like. The user may update the viewed portion of the abstract quantum circuit, such as by scrolling, changing a zoom level, focusing on a searched element, or the like. In some cases, the user may change hierarchical level shown by the GUI (630). In some exemplary embodiments, the user may drill down to view an element at a lower hierarchy level. Additionally, or alternatively, the user may return to higher hierarchical level after reviewing or updating the portion of the lower hierarchy level.

The user may continue to view, review, correct, edit, and modify the abstract quantum circuit using the GUI (615, 620). In response to user instructions and interactions, the display may be modified.

In Step 640, the abstract quantum circuit may be compiled. In some exemplary embodiments, compilation may be initiated in response to a user instruction to compile the abstract quantum circuit, to view quantum circuit, or the like. During compilation of the abstract quantum circuit, the abstract instance may be concretized and replaced, such as by performing Steps 642-644.

In Step 642, a plurality of (non-abstract) instances may replace the single abstract instance. The plurality of instances may implement the same module as defined by the abstract instance. The number of instances that replace the single abstract instance may be determined based on the abstract command. For example, an instance instruction may indicate a number of instances. As another example, the ratio between a width of an input pin that is cascaded, with a width of a register fed to such input pin, may define the number of instances. As yet another example, the parameter of an app parameter instruction may define a number of instances based on the number of digits in a binary representation of the parameter value. In some exemplary embodiments, the definition of the module may be based on the value of the index parameter. In such cases, each instance may be implemented differently, in view of the different value of the index parameter. Additionally, or alternatively, if app parameter instruction is utilized, some instances may have an internal module replaced with an identity module.

In Step 644, new wires may be added to the quantum circuit to connect the plurality of instances. In some cases, such as in case of an instance instruction, the qubit value may be passed sequentially, based on a mapping of output pins to input pins, between each pair of consecutive instances. Additionally, or alternatively, in case of a cascade instruction, the wires may not pass the qubit values sequentially and instead cascade a large register so that different sub-portions thereof are handled by different instances.

In some exemplary embodiments, Step 640 may include invoking a compiler, a transpiler, or the like. In some cases, compilation may be performed in several steps, such as concretizing the abstract quantum circuit to obtain a first quantum circuit in a DAG format and in a functional level. The first quantum circuit in a DAG format may be compiled to obtain a second quantum circuit in gate-level. The second quantum circuit may be compiled to obtain a third quantum circuit which defines a scheduling order of gates over cycles. The third quantum circuit may be compiled to match a target hardware execution platform, obtaining a executable quantum circuit. In some cases, error correction may be implemented in the quantum circuit, such as may be introduced in one of the compilation steps (e.g., a surface code implementation) or in an additional compilation step.

In some exemplary embodiments, the user may view, using the GUI, the concretized quantum circuit. Such a display may be useful for the designer to understand how the abstract commands are interpreted and what circuit is created based thereon. In some cases, the concrete quantum circuit that is being displayed may be in DAG format. Additionally, or alternatively, any other format may also be shown, in between the first quantum circuit and the final executable quantum circuit.

On Step 650, the compiled quantum circuit may be executed on a quantum execution platform such as a quantum computer, a simulator, the quantum cloud, or the like.

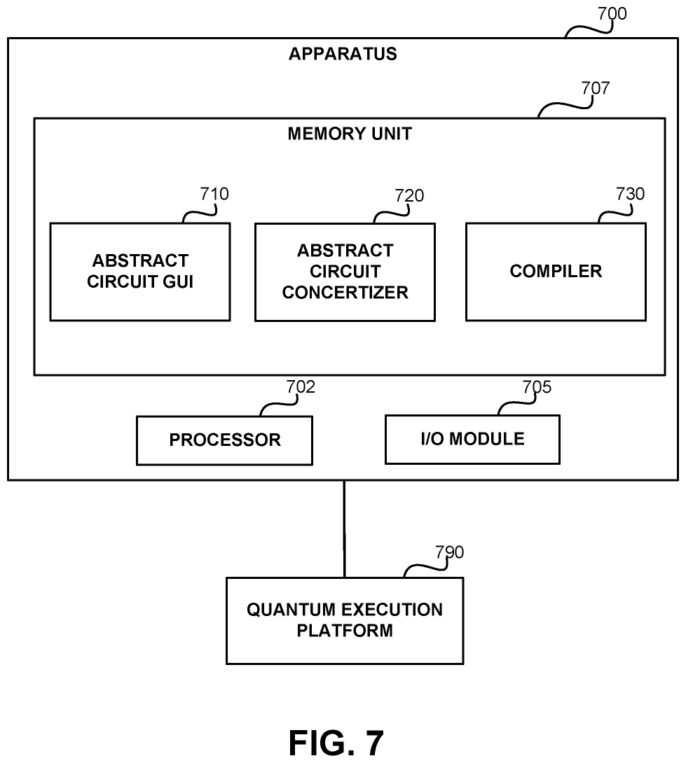

Referring now to FIG. 7 showing an exemplary block diagram of an apparatus, in accordance with some exemplary embodiments of the disclosed subject matter.

In some exemplary embodiments, Apparatus 700 may comprise one or more Processor(s) 702. Processor 702 may be a Central Processing Unit (CPU), a microprocessor, an electronic circuit, an Integrated Circuit (IC) or the like. Processor 702 may be utilized to perform computations required by Apparatus 700 or any of its subcomponents. It is noted that Processor 702 may be a traditional classical processor, and not necessarily a quantum processor.

In some exemplary embodiments of the disclosed subject matter, Apparatus 1200 may comprise an Input/Output (I/O) module 705. I/O Module 705 may be utilized to provide an output to and receive input from a user, an apparatus, or the like, such as, for example, to obtain a quantum program from a user, display the GUI to the user, receive user instructions from the user, or the like. In some cases, I/O Module 705 may include a keyboard, a mouse, a touchscreen, a screen display, a pointing device, or the like.

In some exemplary embodiments, Apparatus 700 may comprise Memory Unit 707. Memory Unit 707 may be a hard disk drive, a Flash disk, a Random Access Memory (RAM), a memory chip, or the like. In some exemplary embodiments, Memory Unit 707 may retain program code operative to cause Processor 702 to perform acts associated with any of the subcomponents of Apparatus 700. Memory Unit 707 may comprise one or more components as detailed below, implemented as executables, libraries, static libraries, functions, or any other executable components.

In some exemplary embodiments, Memory Unit 707 may comprise an Abstract Circuit GUI 710. Abstract Circuit GUI 710 may be configured to display to a user and allow the user to view, edit, and modify an abstract quantum circuit. Abstract Circuit GUI 710 may enable the user to provide abstract commands so as to define abstract instances within the quantum circuit. Abstract Circuit GUI 710 may be a what-you-see-is-what-you-get (WYSIWYG) GUI editor, enabling the user to design the abstract quantum circuit. Additionally, or alternatively, Abstract Circuit GUI 710 may be a drag-and-drop-based GUI, allowing the user to move elements within the abstract quantum circuit, add new elements by dragging them to the desired location and by dropping them, or the like. In some exemplary embodiments, Abstract Circuit GUI 710 may be an hierarchical GUI, enabling the user to drill-down to view details of higher-level abstractions, such as drilling-down on an instance (abstract or not) implementing a module to view and potentially edit the definition of the module. In some exemplary embodiments, Abstract Circuit GUI 710 may be configured to load the abstract quantum circuit from storage, to store updated abstract quantum circuit to storage, or the like. The user may edit the abstract quantum circuit from scratch or from an initial template, or pre-existing circuit, which may or may not be abstract.

In some exemplary embodiments, Memory Unit 707 may comprise Abstract Circuit Concertizer 720. Abstract Circuit Concertizer 720 may be configured to concretize an abstract circuit by replacing an abstract instance of a module with a plurality of (non-abstract) instances of the module. The replacement may be performed so as to be in line with the abstract command and the definition of the module. Abstract Circuit Concertizer 720 may add wires to the quantum circuit to connect the plurality of instances instead of the abstract instance.

In some exemplary embodiments, Memory Unit 707 may comprise Compiler 730. Compiler 730 may comprise a front-end compiler, a back-end compiler, an online compiler, a batch compiler, or the like. In some exemplary embodiments, Compiler 730 may be configured to obtain the a quantum program generated by Abstract Circuit Concertizer 720 and compile it to provide an executable quantum circuit. The executable quantum circuit may be transferred to Quantum Execution Platform 790 to be executed thereby.

The present disclosed subject matter may be a system, a method, and/or a computer program product. The computer program product may include a computer readable storage medium (or media) having computer readable program instructions thereon for causing a processor to carry out aspects of the present disclosed subject matter.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), electrical signals transmitted through a wire, Quantum Random Access Memory (QRAM), photons, trapped ions, lasers, cold atoms, or the like.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosed subject matter may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server (or a group of multiple remote servers). In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosed subject matter.

Aspects of the present disclosed subject matter are described herein with reference to flowchart illustrations and/or block diagrams of methods, apparatus (systems), and computer program products according to embodiments of the disclosed subject matter. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosed subject matter. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the disclosed subject matter. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosed subject matter has been presented for purposes of illustration and description but is not intended to be exhaustive or limited to the disclosed subject matter in the form disclosed. Many modifications and variations will be apparent to those of ordinary skill in the art without departing from the scope and spirit of the disclosed subject matter. The embodiment was chosen and described in order to best explain the principles of the disclosed subject matter and the practical application, and to enable others of ordinary skill in the art to understand the disclosed subject matter for various embodiments with various modifications as are suited to the particular use contemplated.

What is claimed is:

1. A method comprising:
displaying, via a Graphical User Interface (GUI), a first portion of an abstract quantum circuit, wherein the GUI enables a user to view a graphical representation of the abstract quantum circuit, the abstract quantum circuit represents a quantum circuit, the abstract quantum circuit comprises:
one or more input ports, each of which representing an input register;
one or more output ports, each of which representing an output register;
one or more instances of modules, each of which having a set of one or more input pins and a set of one or more output pins, wherein each of the modules represents an operation to be performed on values inputted on the set of one or more input pins causing output to be provided on the set of one or more output pins; and
wires, each of which connecting between a value feeding element and a value receiving element, the value feeding element is one of an output pin and an input port, the value receiving element is one of an output port and an input pin;
wherein at least one of the instances is an abstract instance of a module, the module representing a quantum operation, the abstract instance representing a duplication of the quantum operation within the quantum circuit;
in response to a user instruction to the GUI, changing presented display to the user, whereby showing to the user a second portion of the abstract quantum circuit; and
compiling the abstract quantum circuit to obtain the quantum circuit, wherein said compiling comprises replacing the abstract instance with a plurality of instances of the module, whereby concretizing the abstract instance.

2. The method of claim 1, wherein the abstract instance is presented in the GUI with an instance instruction, the instance instruction indicates a number of times the module is to be duplicated and connected sequentially, whereby defining a number of the plurality of instances of the module that replace the abstract instance.

3. The method of claim 2,
wherein the module comprising an input pin set and an output pin set, a number of input pins in the input pin set is equal to a number of output pins in the output pin set,
wherein the plurality of instances of the module comprises a first instance and a second instance,
wherein said replacing the abstract instance with the plurality of instances further comprises:
for each output pin in the output pin set of the first instance, adding a wire that connects the each output pin with a different input pin of the input pin set of the second instance, whereby each input pin in the input pin set of the second instance is configured to receive a value that is fed from a different output pin in the output pin set of the first instance, whereby creating a sequence of instances that pass values therebetween.

4. The method of claim 3, wherein a mapping between output pin set of the first instance and between the input pin set is defined based on a definition of the module.

5. The method of claim 4, wherein the mapping is defined based on an order of the input pin set in the module and the output pin set in the module, whereby enabling the user to change the mapping via the GUI by editing the module.

6. The method of claim 4, wherein the mapping is defined based on displayed height order of input and output ports in a definition of the module, whereby enabling the user to change the mapping via the GUI by editing the module.

7. The method of claim 1,
wherein the abstract instance is presented in the GUI with a cascade instruction, the cascade instruction indicates an input pin of the module that is configured to receive different subsets of register value fed to the input pin, wherein said replacing the abstract instance with the plurality of instances of the module comprises:
dividing a size of the register value fed to the input pin by a size of the register to be received by the input pin, whereby computing a number of the plurality of instances to be used to replace the abstract instance; and
for each instance of the plurality of instances, feeding a different subset of the register value to a respective input pin thereof, whereby duplicating the quantum operation within the quantum circuit each time with respect to a different portion of the register value.

8. The method of claim 7,
wherein the size of the register to be received by the input pin is N,
wherein the size of the register value fed to the input pin is M,
wherein the number of the plurality of instances is M N,
wherein instance number i of the plurality of instances is fed with bits of range [N·(i−1) . . . (N·i)−1] from the register value, whereby defining the different portion using different offsets in the register value.

9. The method of claim 1, wherein the abstract instance is presented in the GUI with an app parameter instruction, the app parameter instruction indicates, for each instance of the plurality of instances, whether an internal module of the module is to be replaced by an identity module within the instance.

10. The method of claim 9, wherein the app parameter instruction has a value parameter, the value parameter defines for an i-th instance of the plurality of instances whether to use the internal module or to replace the internal module with the identity module, based on a value of the i-th digit of the value parameter in binary basis.

11. The method of claim 1 further comprises: in response to an edit user instruction to the GUI, modifying an abstract command associated with the abstract instance, wherein the abstract command effects a manner in which the abstract instance is replaced in said replacing, thereby changing how the abstract instance is concretized.

12. The method of claim 11, wherein the abstract command is at least one of:
a cascade instruction or a parameter thereof;
an instance instruction or a parameter thereof;
an app parameter instruction or a parameter thereof, wherein the app parameter instruction defines for different instances to replace an internal module in the module with an identity module; and
a usage of an index parameter in a definition of the module, wherein the usage of the index parameter defines different functionalities for different instances of the module that replace the abstract instance.

13. The method of claim 1, wherein the GUI is a hierarchical GUI enabling editing and display of the abstract quantum circuit, wherein said displaying the first portion of the abstract quantum circuit displays the abstract quantum circuit at a first hierarchical level, wherein the user instruction is an instruction to edit the abstract instance, whereby causing the GUI to display the abstract quantum circuit at a second hierarchical level, the second hierarchical level is a lower level than the first hierarchical level, wherein an input pin of the module is shown in the second hierarchical level as an input port, wherein an output pin of the module is shown in the second hierarchical level as an output port, wherein the module comprises an internal module that is not displayed in the first portion and is displayed in the second portion.

14. The method of claim 13, wherein in the second hierarchical level, an index parameter is utilized in the definition of at least one element in the module, wherein said replacing the abstract instance with a plurality of instances comprises: providing for each instance of the plurality of instances a different value for the index parameter, whereby enabling i-th and j-th instances to differ based on the definition of the at least one element.

15. The method of claim 1 further comprising providing the quantum circuit for execution by a quantum execution platform.

16. An apparatus comprising:
a screen display,
a processor, and
a memory,
wherein said processor being adapted to perform:
displaying on said screen display a Graphical User Interface (GUI), wherein the GUI displays a first portion of an abstract quantum circuit, wherein the GUI enables a user to view a graphical representation of the abstract quantum circuit, the abstract quantum circuit represents a quantum circuit, the abstract quantum circuit comprises:
one or more input ports, each of which representing an input register;
one or more output ports, each of which representing an output register;
one or more instances of modules, each of which having a set of one or more input pins and a set of one or more output pins, wherein each of the modules represents an operation to be performed on values inputted on the set of one or more input pins causing output to be provided on the set of one or more output pins; and
wires, each of which connecting between a value feeding element and a value receiving element, the value feeding element is one of an output pin and an input port, the value receiving element is one of an output port and an input pin;
wherein at least one of the instances is an abstract instance of a module, the module representing a quantum operation, the abstract instance representing a duplication of the quantum operation within the quantum circuit;
in response to a user instruction to the GUI, changing presented display to the user, whereby showing to the user a second portion of the abstract quantum circuit using said screen display; and
compiling the abstract quantum circuit to obtain the quantum circuit, wherein said compiling comprises replacing the abstract instance with a plurality of instances of the module, whereby concretizing the abstract instance.

17. The apparatus of claim 16, wherein the abstract instance is presented in the GUI with an instance instruction, the instance instruction indicates a number of times the module is to be duplicated and connected sequentially, whereby defining a number of the plurality of instances of the module that replace the abstract instance.

18. The apparatus of claim 16,
wherein the abstract instance is presented in the GUI with a cascade instruction, the cascade instruction indicates an input pin of the module that is configured to receive different subsets of register value fed to the input pin, wherein said replacing the abstract instance with the plurality of instances of the module comprises:
dividing a size of the register value fed to the input pin by a size of the register to be received by the input pin, whereby computing a number of the plurality of instances to be used to replace the abstract instance; and
for each instance of the plurality of instances, feeding a different subset of the register value to a respective input pin thereof, whereby duplicating the quantum operation within the quantum circuit each time with respect to a different portion of the register value.

19. The apparatus of claim 16, wherein the GUI is a hierarchical GUI enabling editing and display of the abstract quantum circuit, wherein said displaying the first portion of the abstract quantum circuit displays the abstract quantum circuit at a first hierarchical level, wherein the user instruction is an instruction to edit the abstract instance, whereby causing the GUI to display the abstract quantum circuit at a second hierarchical level, the second hierarchical level is a lower level than the first hierarchical level, wherein an input pin of the module is shown in the second hierarchical level as an input port, wherein an output pin of the module is shown in the second hierarchical level as an output port, wherein the module comprises an internal module that is not displayed in the first portion and is displayed in the second portion.

20. A computer program product comprising a non-transitory computer readable medium retaining program instructions, which program instructions when read by a processor, cause the processor to perform a method comprising:
displaying, via a Graphical User Interface (GUI), a first portion of an abstract quantum circuit, wherein the GUI enables a user to view a graphical representation of the abstract quantum circuit, the abstract quantum circuit represents a quantum circuit, the abstract quantum circuit comprises:
one or more input ports, each of which representing an input register;
one or more output ports, each of which representing an output register;
one or more instances of modules, each of which having a set of one or more input pins and a set of one or more output pins, wherein each of the modules represents an operation to be performed on values inputted on the set of one or more input pins causing output to be provided on the set of one or more output pins; and
wires, each of which connecting between a value feeding element and a value receiving element, the value feeding element is one of an output pin and an input port, the value receiving element is one of an output port and an input pin;
wherein at least one of the instances is an abstract instance of a module, the module representing a quantum operation, the abstract instance representing a duplication of the quantum operation within the quantum circuit;
in response to a user instruction to the GUI, changing presented display to the user, whereby showing to the user a second portion of the abstract quantum circuit; and
compiling the abstract quantum circuit to obtain the quantum circuit, wherein said compiling comprises replacing the abstract instance with a plurality of instances of the module, whereby concretizing the abstract instance.
